(19) United States
(12) Patent Application Publication
(10) Pub. No.: US 2026/0239657 A1
(43) Pub. Date: Aug. 13, 2026

(54) SEMICONDUCTOR DEVICE INCLUDING TWO-DIMENSIONAL MATERIAL, METHOD OF MANUFACTURING THE SEMICONDUCTOR DEVICE, AND ELECTRONIC DEVICE INCLUDING THE SEMICONDUCTOR DEVICE

(71) Applicants: Samsung Electronics Co., Ltd., Suwon-si (KR); President and Fellows Of Harvard College, Cambridge, MA (US)

(72) Inventors: Changhyun KIM, Suwon-si (KR); Elise BRUTSCHEA, Cambridge, MA (US); Hongkun PARK, Cambridge, MA (US); Bingchen DENG, Cambridge, MA (US); Minsu SEOL, Suwon-si (KR); Kyung-Eun BYUN, Suwon-si (KR); Yeonchoo CHO, Suwon-si (KR)

(73) Assignees: Samsung Electronics Co., Ltd., Suwon-si (KR); President and Fellows Of Harvard College, Cambridge, MA (US)

(21) Appl. No.: 19/465,976

(22) Filed: Jan. 30, 2026

Related U.S. Application Data
(60) Provisional application No. 63/756,972, filed on Feb. 11, 2025.

(30) Foreign Application Priority Data
Mar. 20, 2025 (KR) 10-2025-0036129

(51) Int. Cl. H10D 30/47; H10D 30/01

(52) U.S. Cl. CPC H10D 30/481; H10D 30/017

(57) ABSTRACT

Provided are a semiconductor device including a two-dimensional (2D) material, a method of manufacturing the semiconductor device, and an electronic device including the semiconductor device. The semiconductor device includes at least one channel layer including a two-dimensional (2D) semiconductor material, a source electrode and a drain electrode, provided on both sides of each channel layer of the at least one channel layer, and a gate electrode provided on each channel layer of the at least one channel layer, between the source electrode and the drain electrode. Each channel layer of the at least one channel layer includes a source region contacting the source electrode, and a drain region contacting the drain electrode, and at least one of the source region and the drain region includes a metallic grain boundary.

### CROSS-REFERENCE TO RELATED APPLICATIONS

This application is based on and claims priority under 35 U.S.C. § 119 to U.S. Provisional Patent Application No. 63/756,972, filed on Feb. 11, 2025, in the U.S. Patent and Trademark Office, and Korean Patent Application No. 10-2025-0036129, filed on Mar. 20, 2025,in the Korean Intellectual Property Office, the disclosures of which are incorporated by reference herein in their entirety.

### BACKGROUND

### 1. Field

The disclosure relates to a semiconductor device including a two-dimensional (2D) material, a method of manufacturing the semiconductor device, and an electronic device including the semiconductor device.

### 2. Description of the Related Art

Transistors are semiconductor devices configured to perform electrical switching and are used in various semiconductor products such as memories and driving integrated circuits (ICs). As the size of a semiconductor device decreases, the demand for an increase in the number of semiconductor devices that may be integrated into a single wafer increases and the demand for higher operating speeds of the semiconductor devices also increase, and thus, research has been actively conducted to reduce the size of semiconductor devices.

Recently, research has been conducted on using a two-dimensional (2D) material as a means for reducing the size of a semiconductor device. 2D materials have stable and excellent properties even at a small thickness of 1 nm or less, and thus, have gained attention as materials that may avoid performance degradation due to a reduction in the size of a semiconductor device.

### SUMMARY

Provided are a semiconductor device including a two-dimensional (2D) material, a method of manufacturing the semiconductor device, and an electronic device including the semiconductor device.

Additional aspects will be set forth in part in the description which follows and, in part, will be apparent from the description, or may be learned by practice of the presented embodiments.

According to an aspect of the disclosure, a semiconductor includes one or more channel layers comprising a two-dimensional (2D) semiconductor material; a source electrode on a first side of each of the one or more channel layers; a drain electrode on a second side of each of the one or more channel layers; and a gate electrode between the source electrode and the drain electrode and on each of the one or more channel layers, wherein each of the one or more channel layers comprises a source region contacting the source electrode; and a drain region contacting the drain electrode, and wherein at least one of the source region or the drain region comprises a metallic grain boundary.

The metallic grain boundary may include a mirror twin boundary (MTB).

Each of the one or more channel layers may include a channel region having a single crystal structure.

The 2D semiconductor material may include one or more transition metal dichalcogenides (TMDs).

The one or more TMDs may include a transition metal element selected from Mo, W, Nb, V, Ta, Ti, Zr, Hf, Tc, or Re and a chalcogen element selected from S, Se, or Te.

The channel layer may have a thickness of 3 nanometers (nm) or less.

Each of the source electrode and the drain electrode may form at least one of a planar contact or an edge contact with each of the one or more channel layers.

The semiconductor device may further include a gate insulating layer between each of the one or more channel layers and the gate electrode.

The one or more channel layers may include a plurality of the channel layers spaced apart from each other, and the gate electrode may surround the channel layers.

According to another aspect of the disclosure, a method of manufacturing a semiconductor device includes forming a channel layer other on a substrate, the channel layer comprising a plurality of material layers, each of the plurality of material layers comprising a two-dimensional (2D) semiconductor material and laterally bonded to each other such that the plurality of material layers define one or more metallic grain boundaries between the plurality of material layers; forming a source electrode and a drain electrode on the channel layer such that at least one of the source electrode or the drain electrode is formed on a respective one of the one or more metallic grain boundaries; and forming a gate electrode on the channel layer such that gate electrode is between the source electrode and the drain electrode.

The one or more metallic grain boundaries may include a mirror twin boundary (MTB).

The forming of the channel layer including the plurality of material layers laterally bonded to each other may include forming a plurality of nucleation sites on the substrate, and forming the plurality of material layers laterally bonded to each other by epitaxially growing the 2D semiconductor material from the plurality of nucleation sites.

The forming of the channel layer including the plurality of material layers laterally bonded to each other may include forming, on the substrate, a first material layer including the 2D semiconductor material such that the first material layer has a single crystal structure, and forming at least one second material layer laterally bonded to the first material layer by epitaxially growing the 2D semiconductor material from at least one side surface of the first material layer.

A channel region of the channel layer corresponding to the gate electrode may have a single crystal structure.

The 2D semiconductor material may include one or more transition metal dichalcogenides (TMDs).

The one or more TMDs may include a transition metal element selected from Mo, W, Nb, V, Ta, Ti, Zr, Hf, Tc, or Re and a chalcogen element selected from S, Se, or Te.

The channel layer may be formed to have a thickness of 3 nm or less.

According to another aspect of the disclosure, an electronic device includes at least one semiconductor device, wherein each of the at least one semiconductor device includes one or more channel layers including a two-dimensional (2D) semiconductor material, a source electrode one a first side of each of the one or more channel layers; a drain electrode on a second side of each of the one or more channel layers; and a gate electrode between the source electrode and the drain electrode and on each of the one or more channel layers, wherein each of the one or more channel layers comprises a source region contacting the source electrode; and a drain region contacting the drain electrode, and wherein at least one of the source region or the drain region comprises a metallic grain boundary.

The metallic grain boundary may include a mirror twin boundary (MTB).

The one or more channel layers may include a plurality of the channel layers spaced apart from each other, and the gate electrode may surround the channel layers.

### BRIEF DESCRIPTION OF THE DRAWINGS

The above and other aspects, features, and advantages of certain embodiments will be more apparent from the following description taken in conjunction with the accompanying drawings, in which:

FIG. 1 is a cross-sectional view schematically illustrating a semiconductor device, according to at least one example embodiment;

FIG. 2 is a plan view illustrating a channel layer of FIG. 1;

FIGS. 3A to 6B are views for describing a method of manufacturing a semiconductor device, according to at least one example embodiment;

FIGS. 7A to 10B are views for describing a method of manufacturing a semiconductor device, according to another embodiment;

FIG. 11 is a cross-sectional view schematically illustrating a semiconductor device, according to another embodiment;

FIG. 12 is a cross-sectional view schematically illustrating a semiconductor device, according to another embodiment;

FIG. 13 is a cross-sectional view schematically illustrating a semiconductor device, according to another embodiment;

FIG. 14 is a perspective view illustrating a semiconductor device, according to another embodiment;

FIG. 15 is a cross-sectional view taken along line I-I′ of FIG. 14; and

FIGS. 16 and 17 are conceptual views schematically illustrating a device architecture applicable to an electronic device, according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described with reference to the drawings. Like reference numerals denote like elements throughout, and in the drawings, sizes of elements may be exaggerated for clarity and convenience of explanation. Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. The embodiments described below are merely examples, and various modifications may be made from the embodiments.

When an element or layer is referred to as being “on” or “above” another element or layer, the element or layer may be directly on another element or layer or intervening elements or layers. The singular forms include the plural forms unless the context clearly indicates otherwise. When a part “comprises” or “includes” an element in the specification, unless otherwise defined, other elements are not excluded from the part and the part may further include other elements.

The term “above” and similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms as used herein are intended to include the plural forms as well unless the context clearly indicates otherwise. When a part “includes” an element, another element may be further included, rather than excluding the existence of the other element, unless otherwise described. The steps of all methods described herein may be performed in any suitable order unless otherwise indicated herein or otherwise clearly contradicted by context, and are not limited to the described order.

Also, in the specification, the term “ . . . unit” or “module” indicates a unit for processing at least one function or operation, and may be implemented by processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Also, lines or members connecting elements illustrated in the drawings are merely illustrative of functional connections and/or physical or circuit connections. In an actual device, the connections between elements may be represented by various functional connections, physical connections, or circuit connections that are replaceable or added.

The use of any and all examples or exemplary language provided herein is intended merely to better describe the disclosure and does not pose a limitation on the scope of the disclosure unless otherwise claimed.

A two-dimensional (2D) material is a material having a layered structure in which constituent atoms are two-dimensionally bonded and has stable and excellent properties even at a small thickness of 1 nanometers nm or less, and thus, has gained attention as a material that may avoid performance degradation due to a reduction in the size of a three-dimensional (3D) bulk material. For example, in a field-effect transistor using silicon as a channel material, as a channel thickness decreases, mobility decreases and threshold voltage distribution increases, and as a channel length decreases, performance degradation due to short-channel effects increases, and there is a limit to reducing the size of a device. On the other hand, in a field-effect transistor using a 2D semiconductor material as a channel material, comparatively excellent performance may be achieved even at a small thickness of 1 nm or less, short-channel effects may be reduced, and thus, the limitation of reducing the size of a device may be overcome. In a field-effect transistor using a 2D semiconductor material as a channel material, charge carriers generally move in-plane with the 2D semiconductor material, therefore in such field-effect transistors an increase in the resistance is provided at the transition from the 2D semiconductor material to a 3D (e.g., bulk) material of, e.g., an electrode due to, e.g., the charge carrier moving from the in-plane direction to an out-of-plane direction. Thereby, by assisting in the transition from the in-plane to out-of-plane direction, an improvement in the contact resistance between source and drain electrodes and the 2D semiconductor material may be provided.

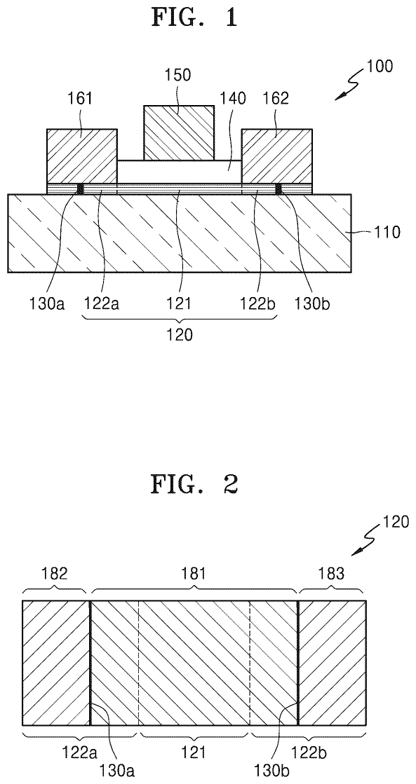

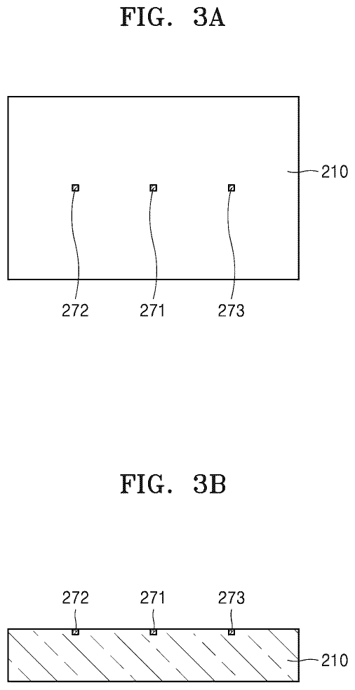

FIG. 1 is a cross-sectional view schematically illustrating a semiconductor device 100, according to at least one example embodiment. The semiconductor device 100 of FIG. 1 may be a field-effect transistor (FET). FIG. 2 is a plan view illustrating a channel layer 120 of FIG. 1.

Referring to FIGS. 1 and 2, the channel layer 120 is provided on a substrate 110. A source electrode 161 and a drain electrode 162 are provided on both sides of the channel layer 120, and a gate insulating layer 140 and a gate electrode 150 are stacked on the channel layer 120 to be disposed between the source electrode 161 and the drain electrode 162.

The substrate 110 may include one or more materials such as a semiconductor material, an insulating material, and/or a metallically conductive material (e.g., a material with a zero-band gap and/or a material with a fermi level in an energy band; hereafter a conductive material). When the channel layer 120 is formed by growing a 2D semiconductor material on the substrate 110, the substrate 110 may be a substrate for growing the 2D semiconductor material. For example, the substrate 110 may include one or more of a group IV semiconductor such as Si, Ge, or SiGe, a group III-V semiconductor compound, sapphire, h-BN, or graphite. However, this is only an example; and the embodiments are not limited thereto.

The source electrode 161 and the drain electrode 162 are provided to respectively conductively contact both sides of the channel layer 120. Each of the source electrode 161 and the drain electrode 162 may include a conductive material having relatively high electrical conductivity, for example, but not limited to, at least one of Ag, Au, Pt, or Cu.

The gate insulating layer 140 and the gate electrode 150 are sequentially stacked on the channel layer 120 to be disposed between the source electrode 161 and the drain electrode 162. The gate insulating layer 140 may include an insulating material, such, for example, but not limited to, silicon oxide, silicon nitride, etc.

The gate electrode 150 may include a conductive material, for example, a metal, a metal nitride, a metal oxide, or a combination thereof. Examples of the metal may include ruthenium (Ru), titanium (Ti), tantalum (Ta), niobium (Nb), iridium (Ir), molybdenum (Mo), tungsten (W), and platinum (Pt). Examples of the metal nitride may include titanium nitride (TiN), tantalum nitride (TaN), niobium nitride (NbN), molybdenum nitride (MoN), cobalt nitride (CoN), and tungsten nitride (WN). Examples of the metal oxide may include platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), and lanthanum strontium cobalt oxide ((La,Sr)CoO₃). The gate electrode 150 may include highly doped polysilicon. The gate electrode 150 may have a single or multi-layer structure. The gate electrode 150 may be electrically isolated from the source electrode 161 and the drain electrode 162.

The channel layer 120 may include a 2D semiconductor material. The 2D semiconductor material refers to a semiconductor material having a layered structure in which constituent atoms are two-dimensionally bonded. The 2D semiconductor material has excellent electrical properties and may maintain high mobility without significantly changing its properties even when a thickness is reduced to a nano-scale.

The 2D semiconductor material constituting the channel layer 120 may include a material having a bandgap of about 0.1 eV or more. For example, the 2D semiconductor material may include a material having a bandgap of 0.1 eV to 2.0 eV. The channel layer 120 may include, for example, transition metal dichalcogenides (TMDs). However, the disclosure is not limited thereto. The TMDs are a 2D material having semiconductor properties and are a compound of a transition metal and a chalcogen element. The transition metal may include at least one of, for example, Mo, W, Nb, V, Ta, Ti, Zr, Hf, Co, Tc, and Re, and the chalcogen element may include at least one of, for example, S, Se, and Te. In a specific example, the TMDs may include MoS₂, MoSe₂, MoTe₂, WS₂, WSe₂, WTe₂, ZrS₂, ZrSe₂, HfS₂, HfSe₂, NbSe₂, or ReSe₂. However, the disclosure is not limited thereto. The 2D semiconductor material may be doped with a p-type dopant or an n-type dopant in order to adjust mobility.

The 2D semiconductor material constituting the channel layer 120 may have a monolayer or multi-layer structure, and each layer may have an atomic level thickness. The channel layer 120 may have a thickness of about 3 nanometers (nm) or less. For example, the channel layer 120 may have a thickness of 0.1 nm to 3 nm. The channel layer 120 may include 1 to 30 layers. In a specific example, the channel layer 120 may include 1 to 10 layers (e.g., 1 to 5 layers), but the disclosure is not limited thereto.

The channel layer 120 may include a channel region 121, and a source region 122a and a drain region 122b respectively provided on both sides of the channel region 121. The channel region 121 is a region where a channel is formed according to a voltage applied to the gate electrode 150 between the source electrode 161 and the drain electrode 162, and may be provided to correspond to the gate electrode 150. The channel region 121 of the channel layer 120 may be provided under the gate electrode 150, that is, at a center portion of the channel layer 120.

The channel region 121 of the channel layer 120 may have a single crystal structure of a 2D semiconductor material. As such, as the channel region 121 has a single crystal structure, off-current caused by leakage current may be reduced, thereby implementing the semiconductor device having comparatively excellent performance.

Each of the source region 122a and the drain region 122b of the channel layer 120 may have a polycrystalline structure of a 2D semiconductor material. In detail, the source region 122a of the channel layer 120 may include a first metallic grain boundary 130a defined by a polycrystal of a 2D semiconductor material, and the drain region 122b of the channel layer 120 may include a second metallic grain boundary 130b defined by a polycrystal of a 2D semiconductor material. Each of the first and second metallic grain boundaries 130a and 130b may be a mirror twin boundary (MTB).

The MTB refers to a grain boundary formed so that lattice structures of adjacent grains are mirror-symmetrical to each other. For example, when an MTB is included in a polycrystalline TMD material, lattice structures of adjacent grains may be arranged at an angle of 60° so that the lattice structures are mirror-symmetrical to each other with respect to the MTB. Such an MTB existing in a 2D material having a polycrystalline structure may form a metallic phase having comparatively excellent conductivity. For example, in at least some embodiments, and without being limited to a specific theory, the gap between the conductive and the valence band of the polycrystalline structure may be less than the gap between the conductive and the valence band of the crystalline structure, thereby a conductivity of the first metallic grain boundary 130a may be greater than in the channel region 121. Further, in at least some embodiments, and without being limited to a specific theory, the grain boundary may assist in the transition of the charge carriers from the in-plane direction to an out-of-plane direction, thereby further reducing the contact resistance between the source electrode 161 and the channel layer 120.

In FIG. 2, the channel layer 120 includes three material layers (e.g., 181, 182, and 183) laterally bonded to each other on the substrate 110. Each of the three material layers (e.g., 181, 182, and 183) includes a 2D semiconductor material having a single crystal structure.

Referring to FIG. 2, the channel layer 120 includes a first material layer 181, and second and third material layers 182 and 183 bonded to both sides of the first material layer 181. The channel region 121 of the channel layer 120 may correspond to a center portion of the first material layer 181. Accordingly, the channel region 121 may be formed of the first material layer 181 having a single crystal structure. The source region 122a of the channel layer 120 may include the first material layer 181 and the second material layer 182, and the first metallic grain boundary 130a may be formed at a boundary between the first material layer 181 and the second material layer 182. Also, the drain region 122b of the channel layer 120 may include the first material layer 181 and the third material layer 183, and the second metallic grain boundary 130b may be formed at a boundary between the first material layer 181 and the third material layer 183. The first and second metallic grain boundaries 130a and 130b may be MTBs having comparatively excellent conductivity as described above.

The source electrode 161 may be provided on the source region 122a including the first metallic grain boundary 130a, and the drain electrode 162 may be provided on the drain region 122b including the second metallic grain boundary 130b. The source electrode 161 may be provided to contact a top surface of the source region 122a of the channel layer 120, and the drain electrode 162 may be provided to contact a top surface of the drain region 122b of the channel layer 120. Accordingly, each of the source electrode 161 and the drain electrode 162 may be provided to form a planar contact with the channel layer 120.

Because the source region 122a of the channel layer 120 contacting the source electrode 161 includes an MTB having comparatively excellent conductivity, contact resistance between the source region 122a of the channel layer 120 and the source electrode 161 may be reduced. Also, because the drain region 122b of the channel layer 120 contacting the drain electrode 162 includes an MTB having comparatively excellent conductivity, contact resistance between the drain region 122b of the channel layer 120 and the drain electrode 162 may be reduced.

In the semiconductor device 100 according to at least one example embodiment, because a 2D semiconductor material is used as a channel material, comparatively excellent performance may be achieved even at a small thickness of 1 nm or less, and because short-channel effects may be reduced, performance degradation due to a reduction in the size of the semiconductor device 100 may be avoided. Also, because the channel region 121 of the channel layer 120 includes a 2D semiconductor material of a single crystal structure, channel resistance in the channel region 121 may be reduced, and thus, on-current may be improved. Also, because the source region 122a and the drain region 122b of the channel layer 120 include a 2D semiconductor material of a polycrystalline structure including an MTB having excellent conductivity, contact resistance in the source region 122a and the drain region 122b of the channel layer 120 may be reduced.

FIGS. 3A to 6B are views for describing a method of manufacturing a semiconductor device, according to at least one example embodiment.

FIGS. 3A and 3B are a plan view and a cross-sectional view illustrating a state where a plurality of nucleation sites (e.g., 271, 272, and 273) are formed on a top surface of a substrate 210. Referring to FIGS. 3A and 3B, the plurality of nucleation sites (e.g., 271, 272, and 273) are formed by forming a pattern (not shown) for nucleation site formation on a top surface of the substrate 210 and then performing, for example, Ar ion milling or laser treatment, on the pattern. In FIGS. 3A and 3B, three nucleation sites, that is, first, second, and third nucleation sites 271, 272, and 273, are formed on the top surface of the substrate to be spaced apart from each other. Each of the first, second, and third nucleation sites 271, 272, and 273 may include a source material for epitaxially growing a 2D semiconductor material, for example, a TMD material, on the top surface of the substrate 210.

The substrate 210 may include at least one of a semiconductor material, an insulating material, or a metal material. For example, the substrate 210 may include a group IV semiconductor such as Si, Ge, or SiGe, a group III-V semiconductor compound, sapphire, h-BN, or graphite. However, the disclosure is not limited thereto.

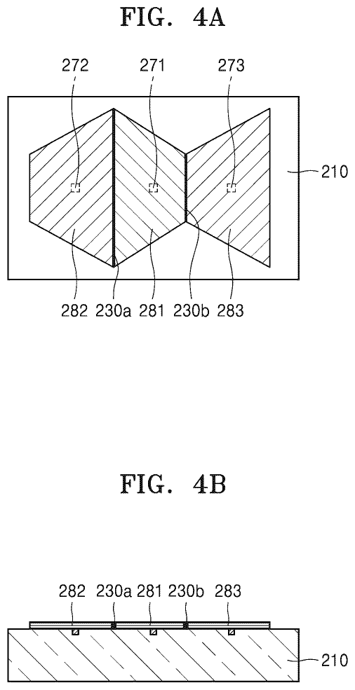

FIGS. 4A and 4B are a plan view and a cross-sectional view illustrating a state where three material layers (e.g. 281, 282, and 283) laterally bonded to each other are formed on a top surface of the substrate 210. Referring to FIGS. 4A and 4B, a 2D semiconductor material is grown through epitaxial growth on each of the first, second, and third nucleation sites 271, 272, and 273 provided on the top surface of the substrate 210. As such, the 2D plane 2D semiconductor material may be parallel (or substantially parallel to) the top surface of the substrate 210. The 2D semiconductor material may include, for example, transition metal dichalcogenides (TMDs). The TMDs are a compound of a transition metal and a chalcogen element. The transition metal may include at least one of, for example, Mo, W, Nb, V, Ta, Ti, Zr, Hf, Co, Tc, and Re, and the chalcogen element may include at least one of, for example, S, Se, and Te. In a specific example, the TMDs may include MoS₂, MoSe₂, MoTe₂, WS₂, WSe₂, WTe₂, ZrS₂, ZrSe₂, HfS₂, HfSe₂, NbSe₂, or ReSe₂. However, the disclosure is not limited thereto.

Accordingly, the first, second, and third material layers 281, 282, and 283 grown on the first, second, and third nucleation sites 271, 272, and 273 and laterally bonded to each other may be formed on the top surface of the substrate 210. Each of the first, second, and third material layers 281, 282, and 283 may have a single crystal structure of a 2D material. A first metallic grain boundary 230a may be formed at a boundary between the first material layer 281 and the second material layer 282, and a second metallic grain boundary 230b may be formed at a boundary between the first material layer 281 and the third material layer 283 by adjusting a growth condition. Each of the first and second metallic grain boundaries 230a and 230b may be an MTB having excellent conductivity. The MTB has been described above, and thus, a detailed description thereof will be omitted.

Each of the first, second, and third material layers 281, 282, and 283 may have a single or multi-layer structure, and each layer may have an atomic level thickness. Each of the first, second, and third material layers 281, 282, and 283 may have a thickness of about 0.1 nm to about 3 nm. Each of the first, second, and third material layers 281, 282, and 283 may include, for example, but is not limited to, 1 to 30 layers (e.g., 1 to 10 layers).

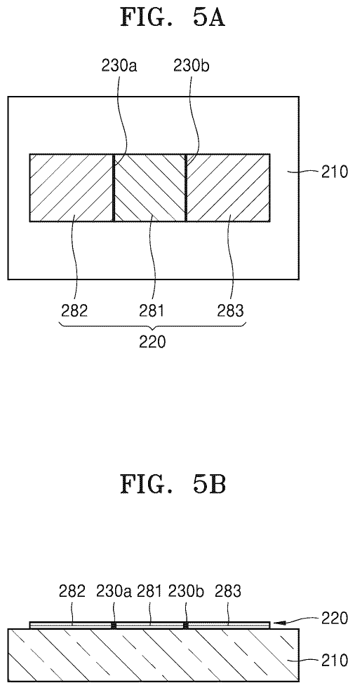

FIGS. 5A and 5B are a plan view and a cross-sectional view illustrating a state where a channel layer 220 is formed on a top surface of the substrate 210. Referring to FIGS. 5A and 5B, the channel layer 220 may be formed by patterning the first, second, and third material layers 281, 282, and 283 laterally bonded to each other illustrated in FIGS. 4A and 4B into a desired shape. In FIGS. 5A and 5B, for convenience of explanation, the first, second, and third nucleation sites 271, 272, and 273 are not shown.

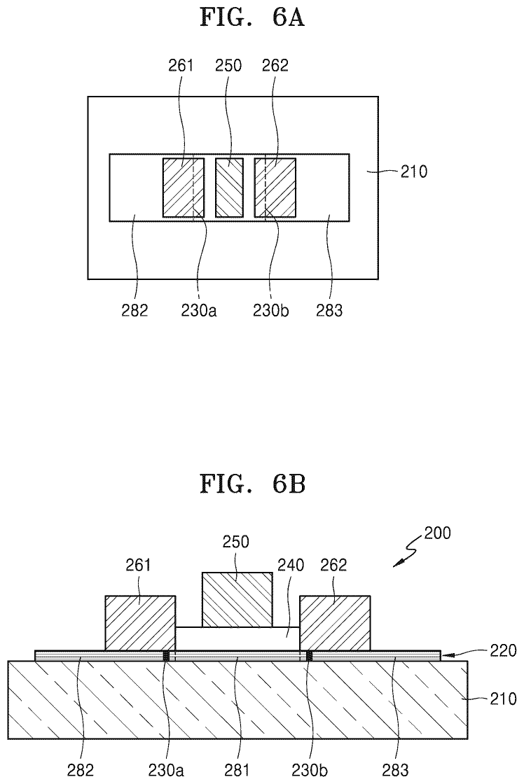

FIGS. 6A and 6B are a plan view and a cross-sectional view illustrating a state where a semiconductor device 200 is completed on the substrate 210. Referring to FIGS. 6A and 6B, a source electrode 261 and a drain electrode 262 are formed on both sides of the channel layer 220. The source electrode 261 may be formed on a top surface of a source region of the channel layer 220. The source region of the channel layer 220 may include the first and second material layers 281 and 282 and the first metallic grain boundary 230a that is a boundary between the first and second material layers 281 and 282. The source electrode 261 may be formed to contact the first metallic grain boundary 230a of the source region. The drain electrode 262 may be formed on a top surface of a drain region of the channel layer 220. The drain region of the channel layer 220 may include the first and third material layers 281 and 283 and the second metallic grain boundary 230b that is a boundary between the first and third material layers 281 and 283. The drain electrode 262 may be formed to contact the second metallic grain boundary 230b of the drain region. Each of the source electrode 261 and the drain electrode 262 may include a metal material having excellent conductivity, for example, but not limited to, Ag, Au, Pt, or Cu.

A gate insulating layer 240 and a gate electrode 250 are sequentially formed on the channel layer 220 to be disposed between the source electrode 261 and the drain electrode 262. The gate insulating layer 240 and the gate electrode 250 may be formed in a channel region of the channel layer 220. The channel region of the channel layer 220 corresponds to a center portion of the first material layer 281, and may have a single crystal structure of a 2D semiconductor material.

The gate insulating layer 240 may include an insulating material, for example, but is not limited to, silicon oxide or silicon nitride. The gate electrode 250 may include a conductive material, for example, a metal, a metal nitride, a metal oxide, or a combination thereof. Examples of the metal may include ruthenium (Ru), titanium (Ti), tantalum (Ta), niobium (Nb), iridium (Ir), molybdenum (Mo), tungsten (W), and platinum (Pt). Examples of the metal nitride may include titanium nitride (TiN), tantalum nitride (TaN), niobium nitride (NbN), molybdenum nitride (MoN), cobalt nitride (CoN), and tungsten nitride (WN). Examples of the metal oxide may include platinum oxide (PtO), iridium oxide (IrO₂), ruthenium oxide (RuO₂), strontium ruthenium oxide (SrRuO₃), barium strontium ruthenium oxide ((Ba, Sr)RuO₃), calcium ruthenium oxide (CaRuO₃), and lanthanum strontium cobalt oxide ((La, Sr)CoO₃). The gate electrode 250 may include highly doped polysilicon. The gate electrode 250 may have a single or multi-layer structure.

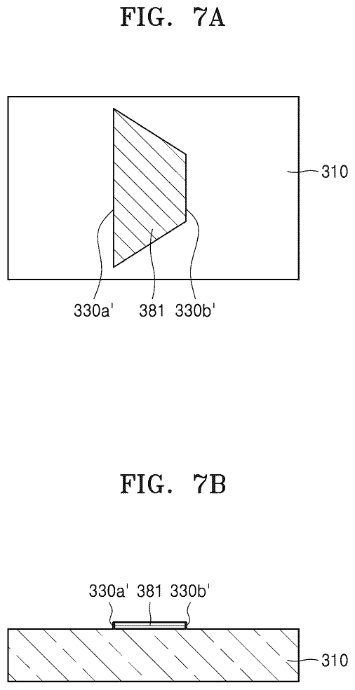

FIGS. 7A to 10B are views for describing a method of manufacturing a semiconductor device, according to at least one example embodiment. Hereinafter, a difference from the above embodiments will be mainly described.

FIGS. 7A and 7B are a plan view and a cross-sectional view illustrating a state where a first material layer 381 is formed on a top surface of a substrate 310. Referring to FIGS. 7A and 7B, the first material layer 381 may be formed by forming a 2D semiconductor material layer having a single crystal structure on a top surface of the substrate 310 through epitaxial growth and patterning the 2D semiconductor material layer into a desired shape. Accordingly, first and second edges 330a′ and 330b′ for lateral growth of a 2D semiconductor material may be formed on both sides of the first material layer 381.

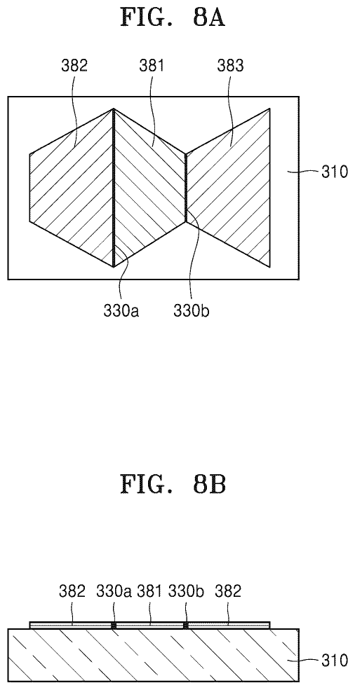

FIGS. 8A and 8B are a plan view and a cross-sectional view illustrating a state where three material layers (e.g., 381, 382, and 383) laterally bonded to each other are formed on a top surface of the substrate 310. Referring to FIGS. 8A and 8B, a 2D semiconductor material is laterally grown at the first edge 330a′ of the first material layer 381 and a 2D semiconductor material is laterally grown at the second edge 330b′ of the first material layer 281 illustrated in FIGS. 7A and 7B. Accordingly, second and third material layers 382 and 383 laterally bonded to the first material layer 381 may be formed on both sides of the first material layer 381.

Each of the first, second, and third material layers 381, 382, and 383 may have a single crystal structure of a 2D material. A first metallic grain boundary 330a may be formed at a boundary between the first material layer 381 and the second material layer 382, and a second metallic grain boundary 330b may be formed at a boundary between the first material layer 381 and the third material layer 383 by adjusting a growth condition. Each of the first and second metallic grain boundaries 330a and 330b may be an MTB having excellent conductivity.

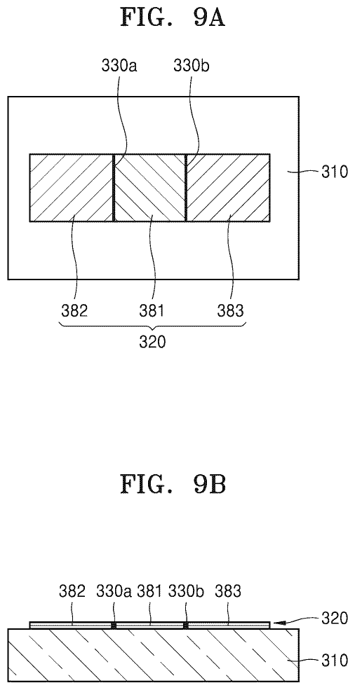

FIGS. 9A and 9B are a plan view and a cross-sectional view illustrating a state where a channel layer 320 is formed on a top surface of the substrate 310. Referring to FIGS. 9A and 9B, the channel layer 320 may be formed by patterning the first, second, and third material layers 381, 382, and 383 laterally bonded illustrated in FIGS. 8A and 8B into a desired shape.

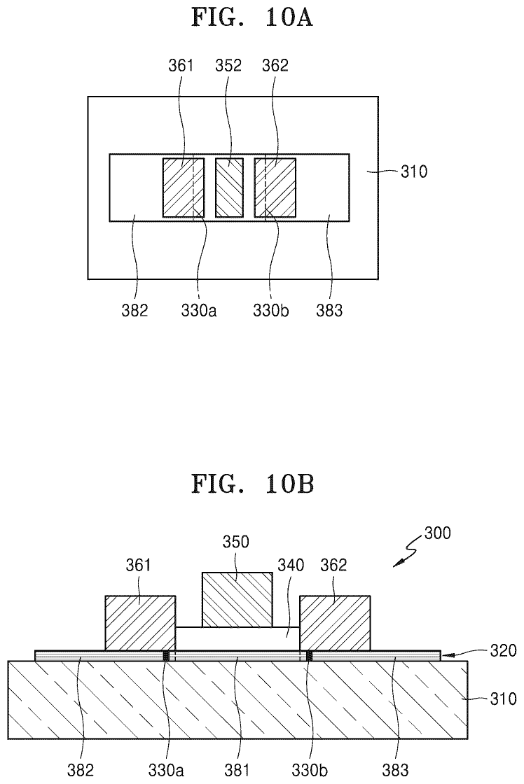

FIGS. 10A and 10B are a plan view and a cross-sectional view illustrating a state where a semiconductor device 300 is completed on the substrate 310. Referring to FIGS. 10A and 10B, a source electrode 361 and a drain electrode 362 are formed on both sides of the channel layer 320. The source electrode 361 may be formed on a top surface of a source region of the channel layer 320. The source region of the channel layer 320 may include the first and second material layers 381 and 382, and the first metallic grain boundary 330a that is a boundary between the first and second material layers 381 and 382. The source electrode 361 may be formed to contact the first metallic grain boundary 330a of the source region. The drain electrode 362 may be formed on a top surface of a drain region of the channel layer 320. The drain region of the channel layer 320 may include the first and third material layers 381 and 383, and the second metallic grain boundary 330b that is a boundary between the first and third material layers 381 and 383. The drain electrode 362 may be formed to contact the second metallic grain boundary 330b of the drain region.

A gate insulating layer 340 and a gate electrode 350 are sequentially formed on the channel layer 320 to be disposed between the source electrode 361 and the drain electrode 362. The gate insulating layer 340 and the gate electrode 350 may be formed in a channel region of the channel layer 320. The channel region of the channel layer 320 corresponds to a center portion of the first material layer 381, and may have a single crystal structure of a 2D semiconductor material.

FIG. 11 is a cross-sectional view schematically illustrating a semiconductor device 400, according to at least one example embodiment. The semiconductor device 400 of FIG. 11 is the same as the semiconductor device 100 of FIG. 1, except that a metallic grain boundary 430 is present only in a source region 422a of a channel layer 420. Hereinafter, a difference from the semiconductor device 100 of FIG. 1 will be mainly described.

Referring to FIG. 11, the channel layer 420 may include a channel region 421, and the source region 422a and a drain region 422b respectively provided on both sides of the channel region 421. The source region 422a of the channel layer 420 may have a polycrystalline structure of a 2D semiconductor material. In detail, the source region 422a of the channel layer 420 may include the metallic grain boundary 430 defined by a polycrystal of a 2D semiconductor material. The metallic grain boundary 430 may be a mirror twin boundary (MTB). The drain region 422b of the channel layer 420 may have a single crystal structure or a polycrystalline structure of a 2D semiconductor material.

The source electrode 161 may be formed on a top surface of the source region 422a of the channel layer 420. The source electrode 161 may be formed to contact the metallic grain boundary 430 of the source region 422a. The drain electrode 162 may be formed on a top surface of the drain region 422b of the channel layer 420. The gate insulating layer 140 and the gate electrode 150 are stacked on the channel layer 420 to be disposed between the source electrode 161 and the drain electrode 162. The gate electrode 150 may be formed to correspond to the channel region 421 of the channel layer 420. The channel region 421 of the channel layer 420 may have a single crystal structure of a 2D semiconductor material.

A case where the source region 422a of the channel layer 420 includes a metallic grain boundary has been described. However, the present embodiment is not limited thereto, and the drain region 422b of the channel layer 420 may include the metallic grain boundary 430.

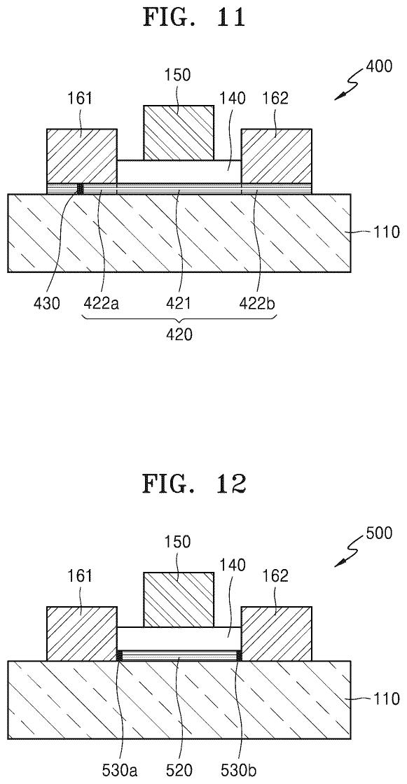

FIG. 12 is a cross-sectional view schematically illustrating a semiconductor device 500, according to another embodiment. The semiconductor device 500 of FIG. 12 is the same as the semiconductor device 100 of FIG. 1, except that the source electrode 161 and the drain electrode 162 form an edge contact with a channel layer 520. Hereinafter, a difference from the semiconductor device 100 of FIG. 1 will be mainly described.

Referring to FIG. 12, the channel layer 520 is provided on the substrate 110, and the source electrode 161 and the drain electrode 162 are respectively provided on both sides of the channel layer 520. The gate insulating layer 140 and the gate electrode 150 are stacked on the channel layer 520 between the source electrode 161 and the drain electrode 162.

Each of the source electrode 161 and the drain electrode 162 may be configured to form an edge contact with the channel layer 520. That is, the source electrode 161 and the drain electrode 162 may be provided to respectively contact side surfaces of both ends of the channel layer 520. The channel layer 520 includes a channel region provided corresponding to the gate electrode 150, and a source region and a drain region provided on both sides of the channel region and respectively contacting the source electrode 161 and the drain electrode 162. The source region may include a first metallic grain boundary 530a provided at one end of the channel layer 520. The source electrode 161 may be provided to contact the first metallic grain boundary 530a. The drain region may include a second metallic grain boundary 530b provided at the other end of the channel layer 520. The drain electrode 162 may be provided to contact the second metallic grain boundary 530b. Each of the first and second metallic grain boundaries 530a and 530b may be a mirror twin boundary (MTB).

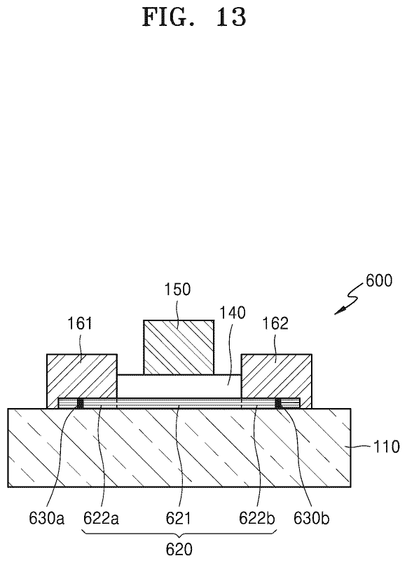

FIG. 13 is a cross-sectional view schematically illustrating a semiconductor device 600, according to another embodiment. The semiconductor device 600 of FIG. 13 is the same as the semiconductor device 100 of FIG. 1, except that the source electrode 161 and the drain electrode 162 form a planar contact and an edge contact with a channel layer 620. Hereinafter, a difference from the semiconductor device of FIG. 1 will be mainly described.

Referring to FIG. 13, the channel layer 620 is provided on the substrate 110, and the source electrode 161 and the drain electrode 162 are respectively provided on both sides of the channel layer 620. The gate insulating layer 140 and the gate electrode 150 are stacked on the channel layer 620 to be disposed between the source electrode 161 and the drain electrode 162.

Each of the source electrode 161 and the drain electrode 162 may be configured to form a planar contact and an edge contact with the channel layer 620. That is, the source electrode 161 and the drain electrode 162 may be provided to contact top and side surfaces of both ends of the channel layer 620. The channel layer 620 includes a channel region 621 provided corresponding to the gate electrode 150, and a source region 622a and a drain region 622b disposed on both sides of the channel region 621 and respectively contacting the source electrode 161 and the drain electrode 162. The source region 622a may include a first metallic grain boundary 630a, and the source electrode 161 may be provided to contact the first metallic grain boundary 630a. Also, the drain region 622b may include a second metallic grain boundary 630b, and the drain electrode 162 may be provided to contact the second metallic grain boundary 630b. Each of the first and second metallic grain boundaries 630a and 630b may be a mirror twin boundary (MTB) described above.

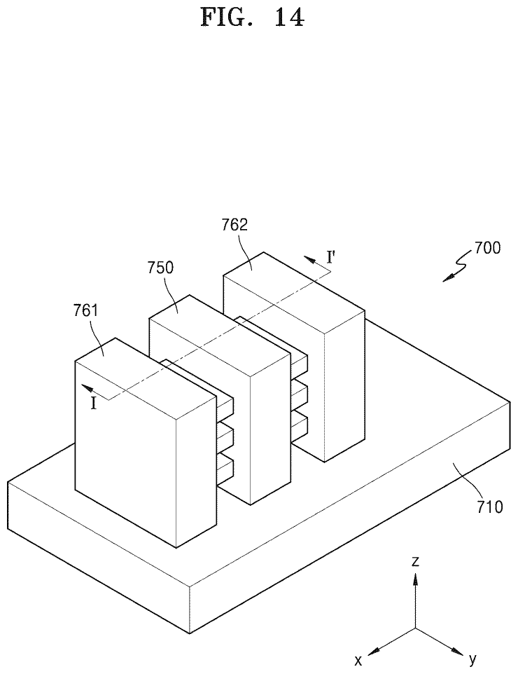

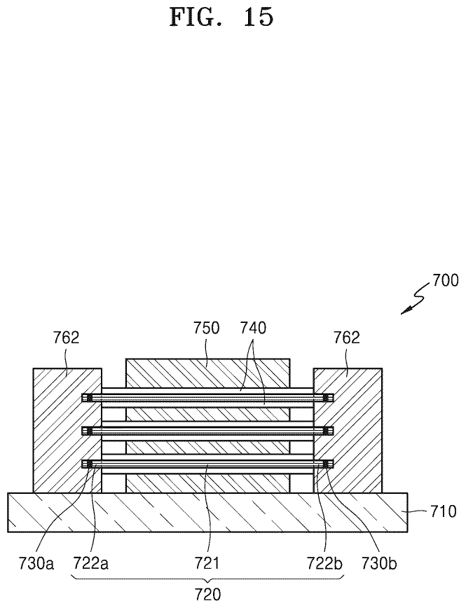

FIG. 14 is a perspective view illustrating a semiconductor device 700, according to another embodiment. FIG. 15 is a cross-sectional view taken along line I-I′ of FIG. 14. The semiconductor device 700 of FIGS. 14 and 15 may be a multi-bridge channel field-effect transistor (MBCFET).

Referring to FIGS. 14 and 15, a plurality of channel layers 720 are provided on a substrate 710 to be spaced apart from each other in a direction perpendicular to the substrate 710. In FIGS. 14 and 15, three channel layers 720 are provided on the substrate 710 to be spaced apart from each other in a direction perpendicular to the substrate.

A source electrode 761 and a drain electrode 762 are respectively provided on both sides of the plurality of channel layers 720. The source electrode 761 and the drain electrode 762 are provided to contact both sides of each channel layer 720. Each of the source electrode 761 and the drain electrode 762 may include a metal material having excellent electrical conductivity, for example, but not limited to, Ag, Au, Pt, or Cu.

A gate electrode 750 is provided on the plurality of channel layers 720 to be disposed between the source electrode 761 and the drain electrode 762. The gate electrode 750 may be provided to surround each of the plurality of channel layers 720. A gate insulating layer 740 is provided between each channel layer 720 and the gate electrode 750. The gate insulating layer 740 is provided to surround four surfaces of each channel layer 720, and the gate electrode 750 is provided to surround four surfaces of the gate insulating layer 740. The gate insulating layer 740 may include, but is not limited to, silicon oxide or silicon nitride. The gate electrode 750 may include, for example, a metal, a metal nitride, a metal oxide, or a combination thereof. The gate electrode 750 may include highly doped polysilicon. The gate electrode 750 may have a single or multi-layer structure.

Each channel layer 720 may include a 2D semiconductor material. The 2D semiconductor material may include a material having a bandgap of about 0.2 eV to about 2.0 eV. For example, the 2D semiconductor material may include a material having a bandgap of 0.1 eV to 2.0 eV. The 2D semiconductor material may include transition metal dichalcogenides (TMDs). According to at least some example embodiments, the TMD may include at least one of MoS₂, MoSe₂, MoTe₂, WS₂, WSe₂, WTe₂, ZrS₂, ZrSe₂, HfS₂, HfSe₂, NbSe₂, or ReSe₂. However, the disclosure is not limited thereto. Each channel layer 720 may have a single or multi-layer structure, and each layer may have an atomic level thickness. Each channel layer 720 may have a thickness of about 0.1 nm to about 3 nm. The channel layer 720 may include, for example, but is not limited to, 1 to 30 layers (e.g., 1 to 10 layers).

Each channel layer 720 may include a channel region 721, and a source region 722a and a drain region 722b respectively provided on both sides of the channel region 721. The channel region 721 of each channel layer 720 is provided corresponding to the gate electrode 750, and may have a single crystal structure of a 2D semiconductor material.

The source region 722a of each channel layer 720 is a region contacting the source electrode 761, may have a polycrystalline structure of a 2D semiconductor material, and may include a first metallic grain boundary 730a. The drain region 722b of each channel layer 720 is a region contacting the drain electrode 732, may have a polycrystalline structure of a 2D semiconductor material, and may include a second metallic grain boundary 730b. Each of the first and second metallic grain boundaries 730a and 730b may be a mirror twin boundary (MTB) described above.

The semiconductor devices 100 to 700 according to embodiments described above may be applied to various electronic devices. For example, the semiconductor devices 100 to 700 may be used in electronic devices such as a mobile device, a computer, a laptop, a sensor, a network device, and a neuromorphic device to perform arithmetic operations, program execution, and temporary data retention.

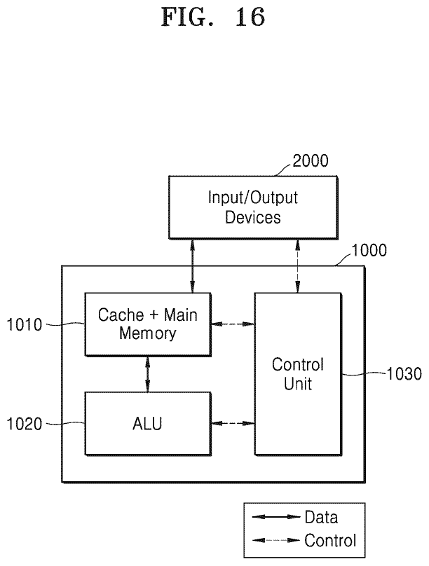

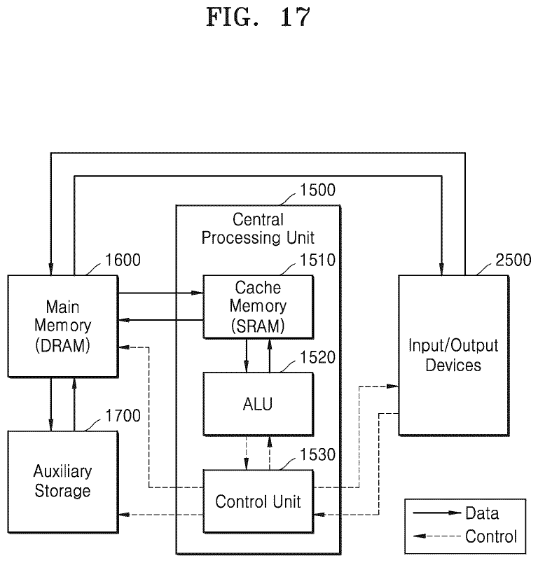

FIGS. 16 and 17 are conceptual views schematically illustrating an electronic device architecture applicable to an electronic device, according to at least one example embodiment.

Referring to FIG. 16, an electronic device architecture 1000 may include a memory unit 1010, an arithmetic logic unit (ALU) 1020, and a control unit 1030. The memory unit 1010, the ALU 1020, and the control unit 1030 may be electrically connected to each other. For example, the device architecture 1000 may be implemented as one chip including the memory unit 1010, the ALU 1020, and the control unit 1030.

In detail, the memory unit 1010, the ALU 1020, and the control unit 1030 may be interconnected through a metal line in an on-chip and may directly communicate with each other. The memory unit 1010, the ALU 1020, and the control unit 1030 may be monolithically integrated on one substrate to constitute one chip. An input/output device 2000 may be connected to the electronic device architecture (chip) 1000.

Each of the ALU 1020 and the control unit 1030 may independently include the semiconductor devices 100 to 700 described above, and the memory unit 1010 may include the semiconductor devices 100 to 700, a capacitor, or a combination thereof. The memory unit 1010 may include both a main memory and a cache memory. The electronic device architecture (chip) 1000 may be an on-chip memory processing unit.

Referring to FIG. 17, a cache memory 1510, an ALU 1520, and a control unit 1530 may constitute a central processing unit (CPU) 1500. The cache memory 1510 may include static random-access memory (SRAM), and may include the semiconductor devices 100 to 700. Aside from the CPU 1500, a main memory 1600 and an auxiliary storage 1700 may be provided. The main memory 1600 may include a dynamic random-access memory (DRAM) device.

In some cases, the electronic device architecture may be implemented in a form in which computing unit devices and memory unit devices are adjacent to each other in one chip, without separating sub-units. While the embodiments have been described in the above, these are merely examples, and it will be understood by one of ordinary skill in the art that various modifications may be made therein without departing from the scope of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A semiconductor device comprising:
one or more channel layers comprising a two-dimensional (2D) semiconductor material;
a source electrode on a first side of each of the one or more channel layers;
a drain electrode on a second side of each of the one or more channel layers; and
a gate electrode between the source electrode and the drain electrode and on each of the one or more channel layers,
wherein each of the one or more channel layers comprises a source region contacting the source electrode; and a drain region contacting the drain electrode, and
wherein at least one of the source region or the drain region comprises a metallic grain boundary.

2. The semiconductor device of claim 1, wherein the metallic grain boundary comprises a mirror twin boundary (MTB).

3. The semiconductor device of claim 1, wherein each of the one or more channel layers comprises a channel region having a single crystal structure, the channel region corresponding to the gate electrode.

4. The semiconductor device of claim 1, wherein the 2D semiconductor material comprises one or more transition metal dichalcogenides (TMDs).

5. The semiconductor device of claim 4, wherein the one or more TMDs comprise:
a transition metal element selected from Mo, W, Nb, V, Ta, Ti, Zr, Hf, Tc, or Re; and
a chalcogen element selected from S, Se, or Te.

6. The semiconductor device of claim 1, wherein each of the one or more channel layers has a thickness of 3 nanometers (nm) or less.

7. The semiconductor device of claim 1, wherein each of the source electrode and the drain electrode forms at least one of a planar contact or an edge contact with each of the one or more channel layers.

8. The semiconductor device of claim 1, further comprising:
a gate insulating layer between the gate electrode and of the one or more channel layers.

9. The semiconductor device of claim 1, wherein the one or more channel layers comprises a plurality of the channel layers spaced apart from each other, and the gate electrode surrounds each of the channel layers.

10. A method of manufacturing a semiconductor device, the method comprising:
forming a channel layer on a substrate, the channel layer comprising a plurality of material layers, each of the plurality of material layers comprising a two-dimensional (2D) semiconductor material and laterally bonded to each other such that the plurality of material layers define one or more metallic grain boundaries between the plurality of material layers;
forming a source electrode and a drain electrode on the channel layer such that at least one of the source electrode or the drain electrode is formed on a respective one of the one or more metallic grain boundaries; and
forming a gate electrode on the channel layer such that gate electrode is between the source electrode and the drain electrode.

11. The method of claim 10, wherein the one or more metallic grain boundaries comprises a mirror twin boundary (MTB).

12. The method of claim 10, wherein the forming of the channel layer comprising the plurality of material layers laterally bonded to each other comprises:
forming a plurality of nucleation sites on the substrate; and
forming the plurality of material layers laterally bonded to each other by epitaxially growing the 2D semiconductor material from the plurality of nucleation sites.

13. The method of claim 10, wherein the forming of the channel layer comprising the plurality of material layers laterally bonded to each other comprises:
forming, on the substrate, a first material layer comprising the 2D semiconductor material such that the first material layer has a single crystal structure; and
forming at least one second material layer laterally bonded to the first material layer by epitaxially growing the 2D semiconductor material from at least one side surface of the first material layer.

14. The method of claim 10, wherein a channel region of the channel layer, corresponding to the gate electrode, has a single crystal structure.

15. The method of claim 10, wherein the 2D semiconductor material comprises one or more transition metal dichalcogenides (TMDs).

16. The method of claim 15, wherein the one or more TMDs comprise:
a transition metal element selected from Mo, W, Nb, V, Ta, Ti, Zr, Hf, Tc, or Re; and
a chalcogen element selected from S, Se, or Te.

17. The method of claim 10, wherein the channel layer is formed to have a thickness of 3 nanometers (nm) or less.

18. An electronic device comprising at least one semiconductor device,
wherein each of the at least one semiconductor device comprises:
one or more channel layers comprising a two-dimensional (2D) semiconductor material;
a source electrode one a first side of each of the one or more channel layers;
a drain electrode on a second side of each of the one or more channel layers; and
a gate electrode between the source electrode and the drain electrode and on each of the one or more channel layers,
wherein each of the one or more channel layers comprises a source region contacting the source electrode; and a drain region contacting the drain electrode, and
wherein at least one of the source region or the drain region comprises a metallic grain boundary.

19. The electronic device of claim 18, wherein the metallic grain boundary comprises a mirror twin boundary (MTB).

20. The electronic device of claim 18, wherein the one or more channel layers comprises a plurality of the channel layers spaced apart from each other, and the gate electrode surrounds of the channel layers.
